(19) United States
(12) Patent Application Publication
(10) Pub. No.: US 2026/0019083 A1
(43) Pub. Date: Jan. 15, 2026

(54) LEVEL SHIFTER

(71) Applicant: EMEMORY TECHNOLOGY INC., HSINCHU (TW)

(72) Inventor: TZU-NENG LAI, HSINCHU COUNTY (TW)

(21) Appl. No.: 19/183,992

(22) Filed: Apr. 21, 2025

Related U.S. Application Data
(60) Provisional application No. 63/671,307, filed on Jul. 15, 2024.

(51) Int. Cl. H03K 19/0944; H03K 19/017; H03K 19/0175; H03K 19/0185

(52) U.S. Cl. CPC H03K 19/0944; H03K 19/01721; H03K 19/017509; H03K 19/018507

(57) ABSTRACT

A level shifter includes first and second transistors, first and second cross-voltage relief circuits, and third and fourth transistors. The first and second transistors are cross-coupled. First terminals of the first and second transistors receive a first high voltage, and second terminals of the first and second transistors output a first and second output voltages respectively. The first cross-voltage relief circuit provides a voltage drop between the first transistor and the third transistor, and the second cross-voltage relief circuit provides a voltage drop between the second transistor and the fourth transistor. The third and fourth transistors respectively receive the first and second input voltages that are complementary to each other. The first input voltage is at a second high voltage lower than the first high voltage or a low voltage lower than the second high voltage.

### CROSS REFERENCE

This application claims the benefit of prior-filed U.S. provisional application No. 63/671,307, filed on Jul. 15, 2024, which is incorporated by reference in its entirety.

### TECHNICAL FIELD

The present disclosure relates to a level shifter, and more particularly, to a level shifter supporting wide input range.

### DISCUSSION OF THE BACKGROUND

A level shifter, also known as a voltage level translator or logic level converter, is an electronic component used to translate signals from one voltage domain to another, ensuring proper communication between components that operate at different voltage domains.

One of the primary challenges faced by the level shifters is the wide range of voltages they need to support. Particularly, as the size of modern electronic components continues to shrink, level shifters are required to support applications with low input voltages accordingly. However, since level shifters need to convert low voltages to high voltages, high-voltage transistors that have higher threshold voltages are usually adopted for better reliability. In such case, if the input voltage is lower than the threshold voltage of the high-voltage transistor, it may cause the level shifter to malfunction. Therefore, how to design a level shifter that supports low input voltage has become an issue to be addressed in the field.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a level shifter. The level shifter includes a first transistor, a second transistor, a first cross-voltage relief circuit, a third transistor, a second cross-voltage relief circuit, and a fourth transistor. The first transistor has a first terminal for receiving a first high voltage, a second terminal for outputting a first output voltage, and a control terminal. The second transistor has a first terminal for receiving the first high voltage, a second terminal for outputting a second output voltage and coupled to the control terminal of the first transistor, and a control terminal coupled to the second terminal of the first transistor. The first cross-voltage relief circuit has a first terminal coupled to the second terminal of the first transistor, and a second terminal, wherein the first cross-voltage relief circuit conducts according to at least one bias voltage to provide a voltage drop between the first terminal and the second terminal of the first cross-voltage relief circuit. The third transistor has a first terminal coupled to the second terminal of the first cross-voltage relief circuit, a second terminal for receiving a first input voltage, and a control terminal for receiving a second high voltage. The second cross-voltage relief circuit has a first terminal coupled to the second terminal of the second transistor, and a second terminal, wherein the second cross-voltage relief circuit conducts according to at least one bias voltage to provide a voltage drop between the first terminal and the second terminal of the second cross-voltage relief circuit. The fourth transistor has a first terminal coupled to the second terminal of the second cross-voltage relief circuit, a second terminal for receiving a second input voltage, and a control terminal for receiving the second high voltage. The first high voltage is higher than the second high voltage, and the first input voltage is complementary to the second input voltage. The first input voltage is at the second high voltage or a low voltage lower than the second high voltage.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a level shifter according to one embodiment of the present disclosure.

FIG. 2 shows a level shifter according to another embodiment of the present disclosure.

FIG. 3 shows a level shifter according to another embodiment of the present disclosure.

FIG. 4 shows a timing diagram of the level shifter in FIG. 3 according to one embodiment of the present disclosure.

FIG. 5 shows a level shifter according to another embodiment of the present disclosure.

FIG. 6 shows a timing diagram of the level shifter in FIG. 5 according to one embodiment of the present disclosure.

### DETAILED DESCRIPTION

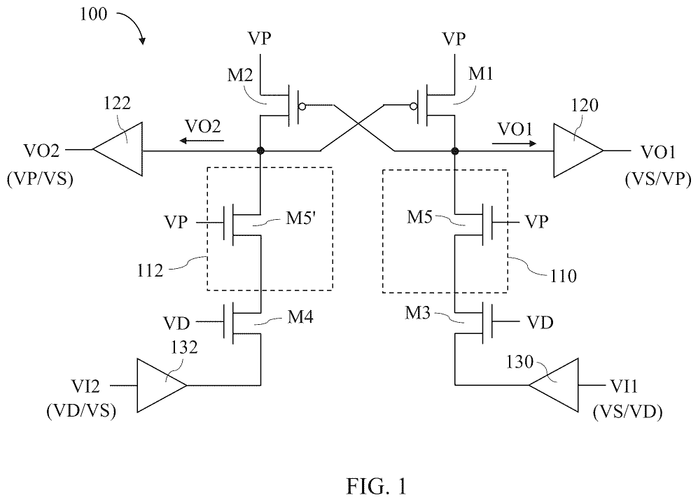

FIG. 1 shows a level shifter 100 according to one embodiment of the present disclosure. The level shifter 100 includes transistors M1 and M2, cross-voltage relief circuits 110 and 112, and transistors M3 and M4.

Specifically, the transistors M1 and M2 can be P-type transistors. The transistor M1 has a first terminal for receiving a first high voltage VP; a second terminal for outputting an output voltage VO1, and a control terminal. The transistor M2 has a first terminal for receiving the first high voltage VP, a second terminal for outputting another output voltage VO2 and coupled to the control terminal of the transistor M1, and a control terminal coupled to the second terminal of the transistor M1.

In the present embodiment, the second terminals of the transistors M1 and M2 can be coupled to buffers 120 and 122 so that the level shifter 100 can output the output voltages VO1 and VO2 through the buffers 120 and 122 with better stability. However, the present disclosure is not limited thereto. In some embodiments, the buffers 120 and 122 may be omitted.

The cross-voltage relief circuit 110 has a first terminal coupled to the second terminal of the transistor M1, and a second terminal. The transistors M3 and M4 can be N-type transistors. The transistor M3 has a first terminal coupled to the second terminal of the cross-voltage relief circuit 110, a second terminal for receiving an input voltage VI1, and a control terminal for receiving a second high voltage VD. In some embodiments, the first high voltage VP and the second high voltage VD can be power voltages in different power domains. In some embodiments, the first high voltage VP is higher than the second high voltage VD. For example, but not limited to, the first high voltage VP can be higher than 2.5V, and the second high voltage VD can be lower than 1V.

The cross-voltage relief circuit 112 has a first terminal coupled to the second terminal of the transistor M2, and a second terminal. The transistor M4 has a first terminal coupled to the second terminal of the cross-voltage relief circuit 112, a second terminal for receiving another input voltage VI2, and a control terminal for receiving the second high voltage VD.

In the present embodiment, the second terminals of the transistors M3 and M4 can be coupled to buffers 130 and 132 so as to receive the input voltages VI1 and VI2 through the buffers 130 and 132 with better stability. However, the present disclosure is not limited thereto. In some embodiments, the buffers 130 and 132 may be omitted. In some embodiments, the buffers 120, 122, 130, and 132 can be inverters.

In the present embodiment, the input voltages VI1 and VI2 are complementary to each other. The transistors M3 and M4 can receive the input voltages VI1 and VI2 in a first voltage domain and controls the cross-coupled transistors M1 and M2 to output the output voltages VO1 and VO2 in a second voltage domain. For example, the input voltages VI1 and VI2 can be changed between the second high voltage VD and a low voltage VS lower than the second high voltage VD, and the output voltages VO1 and V02 can be changed between the first high voltage VP and the low voltage VS. In some embodiments, the low voltage VS can be the ground voltage.

In some embodiments, since the output voltage VO1 and VO2 can be up to 2.5V or higher, the transistors M1 and M2 may be high-voltage transistors that can endure high cross voltages. However, since the input voltage VI1 and VI2 can be lower than 1V and the high-voltage transistors may have threshold voltages higher than 1V, the transistors M3 and M4 may be low-voltage transistors so that the transistors M3 and M4 can function normally according to the low input voltage VI1 and VI2. That is, compared to the transistors M1 and M2, the transistors M3 and M4 can operate at lower voltages, have lower threshold voltages, and are less durable against cross voltages. In some embodiments, the gate oxide of the transistors M1 and M2 can be thicker than the gate oxide of the transistors M3 and M4 so that the transistors M1 and M2 can endure higher cross voltages.

In the present embodiment, to protect the transistors M3 and M4 from being damaged by the high cross voltages when the transistor M1 or M2 outputs the first high voltage VP, the cross-voltage relief circuits 110 and 112 are adopted. The cross-voltage relief circuit 110 can provide a voltage drop between the first terminal and the second terminal of the cross-voltage relief circuit 110, and the cross-voltage relief circuit 112 can provide a voltage drop between the first terminal and the second terminal of the cross-voltage relief circuit 112. As a result, the cross voltages applied to the transistors M3 and M4 can be reduced, thereby allowing the transistors M3 and M4 to be implemented by the low-voltage transistors.

As shown in FIG. 1, the cross-voltage relief circuit 110 includes a transistor M5 (e.g., an N-type transistor). The transistor M5 has a first terminal coupled to the first terminal of the cross-voltage relief circuit 110, a second terminal coupled to the second terminal of the cross-voltage relief circuit 110, and a control terminal for receiving a bias voltage. The bias voltage can be the first high voltage VP in the present embodiment, but this disclosure is not limited thereto. In such case, when the transistor M1 outputs the first high voltage VP, the voltage of the second terminal of the cross-voltage relief circuit 110 would be lower than the voltage of the first terminal of the cross-voltage relief circuit 110 by a threshold voltage of the transistor M5.

In some embodiments, the low-voltage transistors, such as the transistors M3 and M4, can be safely protected if the cross-voltage is lower than the second high voltage VD. In such case, if the difference between the first high voltage VP and the threshold voltage of the transistor M5 is smaller than two times the second high voltage VD, then the transistor M3 would be safely protected. In some embodiments, the transistor M5 can be a high-voltage transistor like the transistor M1 so that the transistor M5 can endure higher cross voltage and provide a greater threshold voltage. Similarly, the cross-voltage relief circuit 112 may include a transistor M5′ (e.g., an N-type transistor). The transistor M5′ has a first terminal coupled to the first terminal of the cross-voltage relief circuit 112, a second terminal coupled to the second terminal of the cross-voltage relief circuit 112, and a control terminal for receiving the bias voltage (e.g., the first high voltage VP).

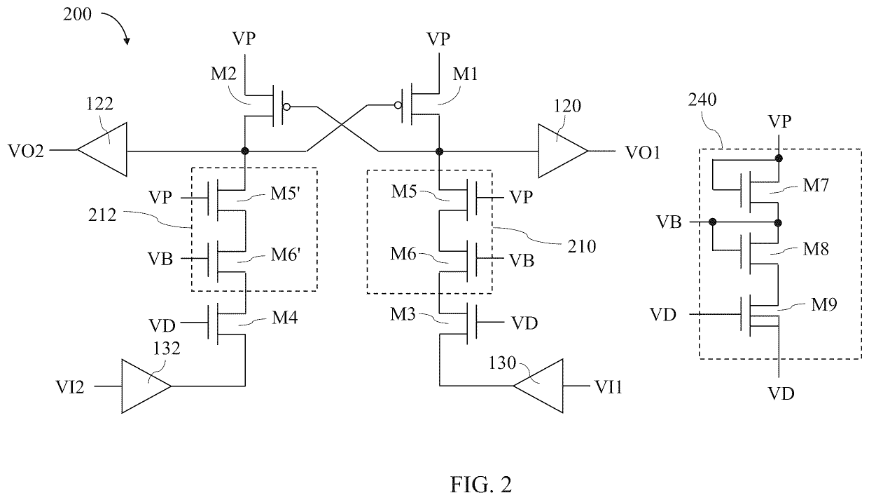

In the embodiment shown in FIG. 1, each of the cross-voltage relief circuit 110 and 112 may include one transistor. However, the present disclosure is not limited thereto. In some embodiments, if the voltage drop provided by the cross-voltage relief circuit 110 or 112 is not enough, more transistors may be cascode so as to provide a greater voltage drop. FIG. 2 shows a level shifter 200 according to another embodiment of the present disclosure.

The level shifter 200 is different from the level shifter 100 in that each of the cross-voltage relief circuits 210 and 212 includes two transistors. For example, the cross-voltage relief circuit 210 includes transistors M5 and M6 (e.g., N-type transistors), and the cross-voltage relief circuit 212 includes transistors M5′ and M6′ (e.g., N-type transistors).

As shown in FIG. 2, the transistor M5 has a first terminal coupled to the first terminal of the cross-voltage relief circuit 210, a second terminal, and a control terminal for receiving the bias voltage (e.g., the first high voltage VP). The transistor M6 has a first terminal coupled to the second terminal of the transistor M5, a second terminal coupled to the second terminal of the cross-voltage relief circuit 210, and a control terminal for receiving another bias voltage VB.

In such case, the cross-voltage relief circuit 210 is able to provide a voltage drop equal to the sum of the threshold voltages of the transistors M5 and M6. In some embodiments, the transistors M5 and M6 can both be high-voltage transistors and have the same threshold voltage Vth. Therefore, when the transistor M1 outputs the first high voltage VP as the output voltage VO1 through its second terminal, the voltage of the first terminal of the transistor M3 would be lower than the first high voltage VP by two times the threshold voltage Vth (i.e., VP-2Vth). In some embodiments, the difference between the first high voltage VP and two times the threshold voltage Vth can be smaller than two times the second high voltage VD, so the cross voltage applied to the transistor M3 can be smaller than the second high voltage VD, thereby ensuring the safety of the transistor M3.

In the present embodiment, the level shifter 200 may further include a bias voltage generator 240 for providing the bias voltage VB required by the transistors M6 and M6′. The bias voltage generator 240 includes transistors M7, M8, and M9 (e.g., N-type transistors). The transistor M7 has a first terminal for receiving the first high voltage VP, a second terminal, and a control terminal coupled to the first terminal of the transistor M7. The transistor M8 has a first terminal coupled to the second terminal of the transistor M7, a second terminal, and a control terminal coupled to the first terminal of the transistor M8. The transistor M9 has a first terminal coupled to the second terminal of the transistor M8, a second terminal for receiving the second high voltage VD, and a control terminal for receiving the second high voltage VD. In such case, the bias voltage VB can be provided from the control terminal of the transistor M8.

Furthermore, in the present embodiment, the transistor M9 remains off to reduce the current consumption of the bias voltage generator 240. However, the present disclosure is not limited thereto. In some embodiments, the transistor M9 can be omitted, and the second terminal of the transistor M8 can receive the second high voltage VD directly. In some embodiments that the first high voltage VP is replaced by a higher voltage, the cross-voltage relief circuit 210 can include one or more additional transistors coupled in series between the transistors M3 and M6 to provide additional voltage drops. In this case, the bias voltage generator 240 can include additional diode-connected transistors coupled in series between the transistors M8 and M9, which provide additional bias voltages to the gates of the additional transistors in the cross-voltage relief circuit 210. Similarly, the cross-voltage relief circuit 212 can include one or more additional transistors coupled in series between the transistors M5′ and M6′, which receive the additional bias voltages from the bias voltage generator 240.

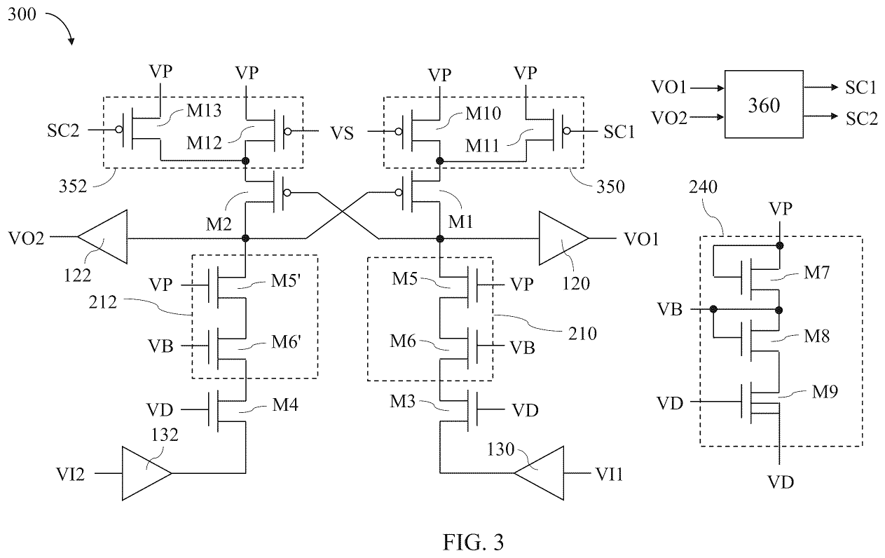

FIG. 3 shows a level shifter 300 according to another embodiment of the present embodiment. The level shifter 300 is different from the level shifter 200 in that the level shifter 300 further includes pull-up circuits 350 and 352. The pull-up circuit 350 is coupled to the first terminal of the transistor M1 and can provide a strong pull-up path to pull up the voltage of the first terminal of the transistor M1 to the first high voltage VP at least when the input voltage VI1 is changed from the low voltage VS to the first high voltage VP. Also, the pull-up circuit 352 is coupled to the first terminal of the transistor M2 and can provide a strong pull-up path to pull up the voltage of the first terminal of the transistor M2 to the first high voltage VP at least when the input voltage VI2 is changed from the low voltage VS to the first high voltage VP. In some embodiments, the pull-up circuits 350 and 352 can help to shorten the transition time of the output voltages VO1 and VO2 as the input voltages VI1 and VI2 change.

As shown in FIG. 3, the pull-up circuit 350 includes transistors M10 and M11 (e.g., P-type transistors). The transistor M10 has a first terminal for receiving the first high voltage VP, a second terminal coupled to the first terminal of the transistor M1, and a control terminal for receiving the low voltage VS. The transistor M11 has a first terminal for receiving the first high voltage VP, a second terminal coupled to the first terminal of the first transistor M1, and a control terminal for receiving a first control signal SC1.

The pull-up circuit 352 includes transistors M12 and M13 (e.g., P-type transistors). The transistor M12 has a first terminal for receiving the first high voltage VP, a second terminal coupled to the first terminal of the transistor M2, and a control terminal for receiving the low voltage VS. The transistor M13 has a first terminal for receiving the first high voltage VP, a second terminal coupled to the first terminal of the transistor M2, and a control terminal for receiving a second control signal SC2.

In some embodiments, the transistor M10 can provide a weak pull-up path for charging the first terminal of the transistor M1 whenever the transistor M1 is turned on or turned off, and the transistor M11 can provide a strong pull-up path for charging the first terminal of the transistor M1 when the input voltage VI1 is changed from the low voltage VS to the second high voltage VD, thereby assisting the transistor M1 to adjust the output voltage VO1 from the low voltage VS to the first high voltage VP sooner. That is, the transistor M11 may have a stronger driving capability than that of the transistor M10. For example, in some embodiments, a width to length ratio of the transistor M11 can be greater than a width to length ratio of the transistor M10 so that the transistor M11 can provide a stronger pull-up path to the first high voltage VP. Similarly, the transistors M12 can provide a weak pull-up path for charging the first terminal of the transistor M2 whenever the transistor M2 is turned on or turned off, and the transistor M13 can provide a strong pull-up path for charging the first terminal of the transistor M2 when the input voltage VI2 is changed from the low voltage VS to the second high voltage VD, thereby assisting the transistor M2 to adjust the output voltage VO2 from the low voltage VS to the first high voltage VP sooner. In such case, a width to length ratio of the transistor M13 may also be greater than a width to length ratio of the transistor M12.

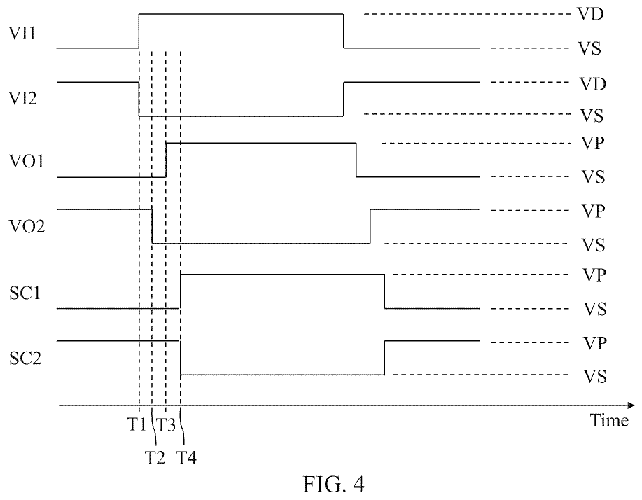

FIG. 4 shows a timing diagram of the level shifter 300 according to one embodiment of the present disclosure. As shown in FIG. 4, the input voltage VI1 is changed from the low voltage VS to the second high voltage VD and the input voltage VI2 is changed from the second high voltage VD to the low voltage VS at the time point T1. Accordingly, the transistor M3 is turned off and stops pulling down the output voltage VOL. Also, the transistor M4 is turned on and starts to pull down the output voltage VO2. Therefore, the output voltage VO2 would be soon changed to the low voltage VS at the time point T2.

As the output voltage VO2 changed to the low voltage VS, the transistor M1 would be turned on. Since the control signal SC1 is at the low voltage VS at this time, the transistor M11 is turned on. In such case, both the transistors M11 and M10 are turned on for pulling up the voltage of the first terminal of the transistor M1 (i.e., the output voltage VO1), so the output voltage VO1 can be soon changed from the low voltage VS to the first high voltage VP at the time point T3.

That is, as shown in FIG. 4, the output voltage VO2 can change from the first voltage VP to the low voltage VS at the time point T2, which occurs before the time point T3 when the output voltage VO1 is changed. Furthermore, since the control signal SC2 is at the first high voltage VP during the transition of the output voltage VO2, the transistor M13 is turned off, so the strong pull-up path provided by the transistor M13 will not be conducted, thereby allowing the transistor M4 to pull down the output voltage VO2 sooner.

After the output voltages VO1 and VO2 are changed according to the transitions of the input voltages VI1 and VI2, the control signal SC1 is changed from the low voltage VS to the first high voltage VP and the control signal SC2 is changed from the first high voltage VP to the low voltage VS at the time point T4 after the time point T3 so as to prepare for the next input voltage transition.

In some embodiments, the level shifter 300 may further include a control unit 360 for generating the control signals SC1 and SC2 according to the output voltages VO1 and VO2. In some embodiments, the control unit 360 may include a delay circuit that can adjust the control signals SC1 and SC2 after a specified delay time following changes in both the output voltages VO1 and VO2.

With the pull-up circuits 350 and 352, the level shifter 300 is able to adjust the output voltages VO1 and VO2 in a higher speed when the input voltages VI1 and VI2 transit.

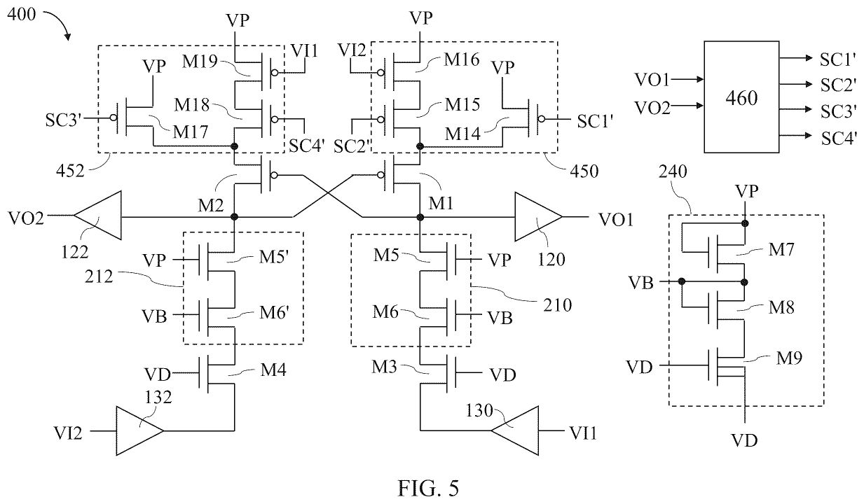

FIG. 5 shows a level shifter 400 according to another embodiment of the present disclosure. The level shifter 400 is different from the level shifter 300 in that the pull-up circuits 450 and 452 may incorporate additional transistors.

The pull-up circuit 450 includes transistors M14, M15, and M16 (e.g., P-type transistors). The transistor M14 has a first terminal for receiving the first high voltage VP, a second terminal coupled to the first terminal of the transistor M1, and a control terminal for receiving a control signal SC1′. The transistor M15 has a first terminal, a second terminal coupled to the first terminal of the transistor M1, and a control terminal for receiving a control signal SC2′. The transistor M16 has a first terminal for receiving the first high voltage VP, a second terminal coupled to the first terminal of the transistor M15, and a control terminal for receiving the input voltage VI2. In the present embodiment, the width to length ratio of the transistor M14 is greater than the width to length ratio of the transistors M15 and M16. Therefore, the transistor M14 can provide a strong pull-up path between the first high voltage VP and the first terminal of the transistor M1, and the transistors M15 and M16 can provide a weak pull-up path between the first high voltage VP and the first terminal of the transistor M1.

The pull-up circuit 452 includes transistors M17, M18 and M19 (e.g., P-type transistors). The transistor M17 has a first terminal for receiving the first high voltage VP, a second terminal coupled to the first terminal of the transistor M2, and a control terminal for receiving a control signal SC3′. The transistor M18 has a first terminal, a second terminal coupled to the first terminal of the transistor M2, and a control terminal for receiving a control signal SC4′. The transistor M19 has a first terminal for receiving the first high voltage VP, a second terminal coupled to the first terminal of the transistor M18, and a control terminal for receiving the input voltage VI1. In the present embodiment, the width to length ratio of the transistor M17 is greater than the width to length ratio of the transistors M18 and M19. Therefore, the transistor M17 can provide a strong pull-up path between the first high voltage VP and the first terminal of the transistor M2, and the transistors M18 and M19 can provide a weak pull-up path between the first high voltage VP and the first terminal of the transistor M2.

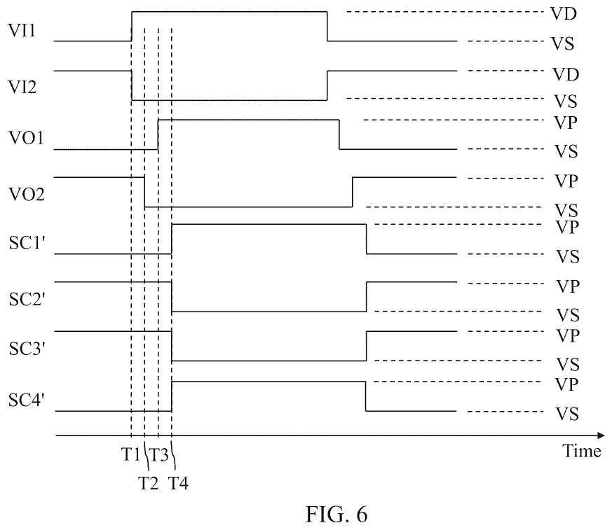

FIG. 6 shows a timing diagram of the level shifter 400 according to one embodiment of the present disclosure. As shown in FIG. 6, the input voltage VI1 is changed from the low voltage VS to the second high voltage VD and the input voltage VI2 is changed from the second high voltage VD to the low voltage VS at the time point T1. Accordingly, the transistor M3 is turned off and stops pulling down the output voltage VOL. Also, the transistor M4 is turned on and starts to pull down the output voltage VO2. Therefore, the output voltage VO2 would be soon changed to the low voltage VS at the time point T2.

As the output voltage VO2 changed to the low voltage VS, the transistor M1 would be turned on. Since the control signal SC1′ is at the low voltage VS at this time, the transistor M14 is turned on, so the output voltage VO1 can be soon changed from the low voltage VS to the first high voltage VP at the time point T3 after the time point T2 due to the aid of the strong pull-up path provided by the transistor M14. In the present embodiment, the control signal SC2′ can be complementary to the control signal SC1′. For example, the control signal SC2′ may be generated by inverting the control signal SC1′. In such case, the transistor M15 is turned off so that the weak pull-up path provided by the transistors M15 and M16 is cut off.

Furthermore, at the time point T2, since the control signal SC3′ is at the first high voltage VP during the transition of the output voltage VO2, the transistor M17 is turned off, so the strong pull-up path provided by the transistor M17 will not be conducted, thereby allowing the transistor M4 to pull down the output voltage VO2 sooner. In the present embodiment, the control signal SC4′ can be complementary to the control signal SC3′. For example, the control signal SC4′ may be generated by inverting the control signal SC3′. In such case, the transistor M18 is turned on and the transistor M19 is turned off so that the weak pull-up path provided by the transistors M18 and M19 is cut off.

After the output voltages VO1 and VO2 are changed according to the transitions of the input voltages VI1 and VI2, the control signal SC1′ is changed from the low voltage VS to the first high voltage VP, the control signal SC2′ is changed from the first high voltage VP to the low voltage VS, the control signal SC3′ is changed from the first high voltage VP to the low voltage VS, and the control signal SC4′ is changed from the low voltage VS to the first high voltage VP at the time point T4 so as to prepare for the next input voltage transition.

In some embodiments, the level shifter 400 may further include a control unit 460 for generating the control signals SC1, SC2′, SC3′ and SC4′ according to the output voltages VO1 and VO2. In some embodiments, the control unit 460 may include a delay circuit that can adjust the control signals SC1′ and SC3′ after a specified delay time following the changes in both the output voltages VO1 and VO2. Also, the control unit 460 may further include inverters for inverting the control signals SC1′ and SC3′ so as to generate the control signals SC2′ and SC4′. However, the present disclosure is not limited thereto.

In some embodiments, if the magnitude relationships between the voltages supplied to the level shifter 100, 200, 300 or 400 are inverted, each N-type transistor in the level shifter may be replaced by a P-type transistor and each P-type transistor in the level shifter may be replaced by an N-type transistor.

In summary, the level shifters provided by the embodiments of the present disclosure can include cross-voltage relief circuits for protecting the input transistors having low threshold voltages, thereby allowing the level shifters to function normally and reliably under for low input voltage. Furthermore, the level shifters may further include pull-up circuits for providing strong pull-up paths and weak pull-up paths so as to increase the speed of the voltage transition and improve the reliability of the level shifters.

What is claimed is:

1. A level shifter comprising:
a first transistor, having a first terminal configured to receive a first high voltage, a second terminal configured to output a first output voltage, and a control terminal;
a second transistor, having a first terminal configured to receive the first high voltage, a second terminal configured to output a second output voltage and coupled to the control terminal of the first transistor, and a control terminal coupled to the second terminal of the first transistor;
a first cross-voltage relief circuit having a first terminal coupled to the second terminal of the first transistor, and a second terminal, wherein the first cross-voltage relief circuit is configured to conduct according to at least one bias voltage to provide a voltage drop between the first terminal and the second terminal of the first cross-voltage relief circuit;
a third transistor having a first terminal coupled to the second terminal of the first cross-voltage relief circuit, a second terminal configured to receive a first input voltage, and a control terminal configured to receive a second high voltage;
a second cross-voltage relief circuit having a first terminal coupled to the second terminal of the second transistor, and a second terminal, wherein the second cross-voltage relief circuit is configured to conduct according to the at least one bias voltage to provide a voltage drop between the first terminal and the second terminal of the second cross-voltage relief circuit; and
a fourth transistor having a first terminal coupled to the second terminal of the second cross-voltage relief circuit, a second terminal configured to receive a second input voltage, and a control terminal configured to receive the second high voltage,
wherein the first high voltage is higher than the second high voltage, and the first input voltage is complementary to the second input voltage, and
wherein the first input voltage is at the second high voltage or a low voltage lower than the second high voltage.

2. The level shifter of claim 1, wherein a gate oxide of the first transistor is thicker than a gate oxide of the third transistor.

3. The level shifter of claim 1, wherein the first cross-voltage relief circuit comprises a fifth transistor having a first terminal coupled to the first terminal of the first cross-voltage relief circuit, a second terminal, and a control terminal configured to receive a first bias voltage of the at least one bias voltage.

4. The level shifter of claim 3, wherein the first bias voltage is the first high voltage.

5. The level shifter of claim 3, wherein the second terminal of the fifth transistor is coupled to the second terminal of the first cross-voltage relief circuit, and a difference between the first high voltage and a threshold voltage of the fifth transistor is smaller than two times the second high voltage.

6. The level shifter of claim 3, wherein the first cross-voltage relief circuit further comprises a sixth transistor having a first terminal coupled to the second terminal of the fifth transistor, a second terminal, and a control terminal configured to receive a second bias voltage of the at least one bias voltage, wherein the second bias voltage is lower than the first bias voltage.

7. The level shifter of claim 6, wherein the second terminal of the sixth transistor is coupled to the second terminal of the first cross-voltage relief circuit, and a difference between the first high voltage and two times a threshold voltage of the fifth transistor is smaller than two times the second high voltage.

8. The level shifter of claim 6, further comprising a bias voltage generator, comprising:
a seventh transistor having a first terminal configured to receive the first high voltage, a second terminal, and a control terminal coupled to the first terminal of the seventh transistor; and
an eighth transistor having a first terminal coupled to the second terminal of the seventh transistor, a second terminal configured to receive the second high voltage, and a control terminal coupled to the first terminal of the eighth transistor and configured to provide the second bias voltage.

9. The level shifter of claim 8, wherein the bias voltage generator further comprises a ninth transistor having a first terminal coupled to the second terminal of the eighth transistor, a second terminal configured to receive the second high voltage, and a control terminal configured to receive the second high voltage.

10. The level shifter of claim 1, further comprising:
a first pull-up circuit coupled to the first terminal of the first transistor and configured to provide a first strong pull-up path and a first weak pull-up path, wherein the first strong pull-up path is configured to pull up a voltage of the first terminal of the first transistor to the first high voltage at least when the first input voltage is changed from the low voltage to the second high voltage; and
a second pull-up circuit coupled to the first terminal of the second transistor and configured to provide a second strong pull-up path and a second weak pull-up path, wherein the second strong pull-up path is configured to pull up a voltage of the first terminal of the second transistor to the first high voltage at least when the second input voltage is changed from the low voltage to the second high voltage.

11. The level shifter of claim 10, wherein the first pull-up circuit comprises:
a tenth transistor having a first terminal configured to receive the first high voltage, a second terminal coupled to the first terminal of the first transistor, and a control terminal configured to receive the low voltage, wherein the tenth transistor is configured to provide the first weak pull-up path; and
an eleventh transistor having a first terminal configured to receive the first high voltage, a second terminal coupled to the first terminal of the first transistor, and a control terminal configured to receive a first control signal, wherein the eleventh transistor is configured to provide the first strong pull-up path.

12. The level shifter of claim 11, wherein a width to length ratio of the eleventh transistor is greater than a width to length ratio of the tenth transistor.

13. The level shifter of claim 11, wherein the second pull-up circuit comprises:
a twelfth transistor having a first terminal configured to receive the first high voltage, a second terminal coupled to the first terminal of the second transistor, and a control terminal configured to receive the low voltage, wherein the twelfth transistor is configured to provide the second weak pull-up path; and
a thirteenth transistor having a first terminal configured to receive the first high voltage, a second terminal coupled to the first terminal of the second transistor, and a control terminal configured to receive a second control signal, wherein the thirteenth transistor is configured to provide the second strong pull-up path.

14. The level shifter of claim 13, wherein:
after the first input voltage is changed from the low voltage to the second high voltage and the second input voltage is changed from the second high voltage to the low voltage, the second output voltage is changed from the first high voltage to the low voltage and the first output voltage is changed from the low voltage to the first high voltage; and
after the second output voltage is changed from the first high voltage to the low voltage and the first output voltage is changed from the low voltage to the first high voltage, the first control signal is changed from the low voltage to the first high voltage and the second control signal is changed from the first high voltage to the low voltage.

15. The level shifter of claim 13, further comprising a control unit configured to generate the first control signal and the second control signal according to the first output voltage and the second output voltage.

16. The level shifter of claim 10, wherein the first pull-up circuit comprises:
a fourteenth transistor having a first terminal configured to receive the first high voltage, a second terminal coupled to the first terminal of the first transistor, and a control terminal configured to receive a first control signal, wherein the fourteenth transistor is configured to provide the first strong pull-up path;
an fifteenth transistor having a first terminal, a second terminal coupled to the first terminal of the first transistor, and a control terminal configured to receive a second control signal; and
a sixteenth transistor having a first terminal configured to receive the first high voltage, a second terminal coupled to the first terminal of the fifteenth transistor, and a control terminal configured to receive the second input voltage, wherein the fifteenth transistor and the sixteenth transistor are configured to provide the first weak pull-up path.

17. The level shifter of claim 16, wherein a width to length ratio of the fourteenth transistor is greater than a width to length ratio of the fifteenth transistor and a width to length ratio of the sixteenth transistor.

18. The level shifter of claim 16, wherein the second pull-up circuit comprises:
a seventeenth transistor having a first terminal configured to receive the first high voltage, a second terminal coupled to the first terminal of the second transistor, and a control terminal configured to receive a third control signal, wherein the seventeenth transistor is configured to provide the second strong pull-up path;
an eighteenth transistor having a first terminal, a second terminal coupled to the first terminal of the second transistor, and a control terminal configured to receive a fourth control signal; and
a nineteenth transistor having a first terminal configured to receive the first high voltage, a second terminal coupled to the first terminal of the eighteenth transistor, and a control terminal configured to receive the first input voltage, wherein the eighteenth transistor and the nineteenth transistor are configured to provide the second weak pull-up path.

19. The level shifter of claim 18, wherein:
after the first input voltage is changed from the low voltage to the second high voltage and the second input voltage is changed from the second high voltage to the low voltage, the second output voltage is changed from the first high voltage to the low voltage and the first output voltage is changed from the low voltage to the first high voltage; and
after the second output voltage is changed from the first high voltage to the low voltage and the first output voltage is changed from the low voltage to the first high voltage, the first control signal is changed from the low voltage to the first high voltage, the second control signal is changed from the first high voltage to the low voltage, the third control signal is changed from the first high voltage to the low voltage, and the fourth control signal is changed from the low voltage to the first high voltage.
